(19) United States
(12) Patent Application Publication
(10) Pub. No.: US 2018/0218905 A1
(43) Pub. Date: Aug. 2, 2018

(54) APPLYING EQUALIZED PLASMA COUPLING DESIGN FOR MURA FREE SUSCEPTOR

(71) Applicant: Applied Materials, Inc., Santa Clara, CA (US)

(72) Inventors: Beom Soo PARK, San Jose, CA (US); Dongsuh LEE, Gilroy, CA (US); Hsiao-Lin YANG, Taipei City (TW); Fu-Ting CHANG, Tainan City (TW); Hsiang AN, Taichung City (TW); Tsung-Yao SU, Taichung City (TW)

(21) Appl. No.: 15/884,129

(22) Filed: Jan. 30, 2018

Related U.S. Application Data
(60) Provisional application No. 62/453,725, filed on Feb. 2, 2017.

(51) Int. Cl. H01L 21/205; H01L 21/02; C23C 16/505; C23C 16/517; C23C 16/44; C23C 16/455; C23C 8/36

(52) U.S. Cl. CPC H01L 21/205; H01L 21/02131; H01L 21/02274; C23C 8/36; C23C 16/517; C23C 16/4405; C23C 16/455; C23C 16/505

(57) ABSTRACT

A method and apparatus for equalized plasma coupling is provided herein. Discontinuity marks, also known as golf tee mura, are eliminated or minimized by biasing or grounding lift pins disposed in openings towards the center of a substrate support. To prevent shorting between a biased or grounded lift pin and the substrate support, lift pins are electrically isolated from the substrate support. The electrical isolation of the lift pin includes coating the lift pins with an electrically insulating material or lining a respective substrate support opening with an electrically insulating material.

### CROSS-REFERENCE TO RELATED APPLICATIONS

This application claims priority to U.S. Provisional Patent Application Ser. No. 62/453,725 filed on Feb. 2, 2017, which is herein incorporated by reference in its entirety.

### BACKGROUND

### Field

Embodiments of the present disclosure generally relate to a substrate support used in flat panel display manufacturing. More particularly, embodiments of the disclosure relate to substrate lift pins for use in a vacuum chamber utilized to deposit materials on flat media, such as rectangular, flexible sheets of glass, plastic, or other material in the manufacture of flat panel displays, photovoltaic devices, or solar cells among other applications.

### Description of the Related Art

Electronic devices, such as thin film transistors (TFT's), photovoltaic (PV) devices or solar cells, and other electronic devices have been fabricated on thin media for many years. Fabricating the electronic devices on substrates having a large surface area, such as two square meters, or larger, produce an end product of a larger size and/or decrease fabrication costs per device (e.g., pixel, TFT, photovoltaic or solar cell, etc.).

Plasma-enhanced chemical vapor deposition (PECVD) is a process in which various materials are deposited on a substrate in order to create a film. Generally, during a PECVD process, the substrate is supported by a substrate support in a vacuum deposition processing chamber and is heated to several hundred degrees Celsius during processing. Deposition gases are injected into the chamber, a plasma is formed of the deposition gases, and a chemical reaction occurs on and, or, with a surface of the substrate, resulting in the deposition of a specific film thereon. The PECVD process is used to manufacture liquid crystal displays, flat panel displays, film transistors as well as other semiconductor devices.

During a PECVD process, plasma distribution affects the quality of the film deposited in terms of both thickness and film properties. If the plasma distribution above the surface of a substrate is not generally uniform, then the quality of the film deposited will not be uniform. One source of non-uniform plasma distribution is unequal energy coupling with the plasma above substrate lift pins disposed in the substrate support. Lift pins are conventionally used to raise the substrate from a substrate receiving surface of the substrate support which provides access to the backside of the substrate by a robot handler for transferring of the substrate to and from the PECVD chamber. Typically, handling schemes for large area substrates use a lift pin configuration having a plurality of lift pins arranged about the edges of the substrate support (edge lift pins) and one or more lift pins arranged towards the center of the substrate support (inner lift pins). The inner lift pins are necessary for large area substrate handling because the weight of large area substrates causes sagging in the middle of the substrate as it is lifted from a substrate support that would, without the inner lift pins, prevent access thereto by the robot handler. Unfortunately, discontinuity marks (visible disruptions in the appearance of the deposited film, also known as golf tee mura) are commonly found on the processed substrate in regions disposed above and, or, proximate to the lift pins.

Conventionally, display screens that do not require large surface areas, such as those for PDA or computer screens, are cut from the large area substrate in a pattern designed to avoid discontinuity marks which might be visible to a consumer. However, the discontinuity marks in the large area substrate remain undesirable as they result in wasted substrate surface area and, therefore, increased manufacturing costs. Further, processes designed to avoid discontinuity marks in the center of a substrate require additional patterning steps and procedures that increase overall manufacturing time. In applications that require large continuous substrate areas, such as large screen television production, such discontinuity marks cannot be avoided.

Accordingly, what is needed in the art are improved apparatus and methods to equalize plasma distribution for large area substrates and substantially eliminate or minimize visible discontinuity marks in and, or, on the surfaces thereof.

### SUMMARY

Embodiments described herein relate to biasing or grounding of one or more lift pins used for large area substrate handling in order to eliminate, or minimize, the appearance of discontinuity marks in the substrate from unequal distribution of the plasma formed thereabove.

In one embodiment, a processing chamber is provided. The processing chamber includes a chamber body defining a processing volume and a substrate support disposed within the processing volume, where the substrate support has a plurality of openings formed therethrough. The processing chamber further includes one or more first lift pins respectively disposed through one or more first openings of the plurality of openings and one or more second lift pins respectively disposed through one or more second opening of the plurality of openings, where the one or more second lift pins are electrically isolated from the substrate support.

In another embodiment, a processing kit is provided. The processing kit includes one or more lift pins. The one or more lift pins each comprise an elongated shaft coupled to a head, the head having a top surface, sides, and a bottom surface and a coating of electrically non-conductive material disposed on the elongated shaft, the sides of the head, and the bottom surface of the head.

In another embodiment, a method of processing a substrate is provided. The method includes positioning a substrate on a substrate support, where the substrate support disposed in a processing volume of a processing chamber, applying a bias voltage to one or more lift pins movably disposed through the substrate support, flowing a processing gas into the processing volume, igniting and maintaining a plasma of the processing gas, exposing the substrate to the plasma, and depositing a material layer on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of a PECVD chamber, according to one embodiment.

FIG. 2A is a schematic plan view of a substrate support having a lift pin configuration in accordance with the prior art.

FIG. 2B is a schematic plans view of a substrate support having a lift pin configuration according to embodiments described herein.

FIG. 3A-3C are close-up views of portions of the substrate support of FIG. 1, according to embodiments described herein.

FIG. 4 is a flow diagram of a method of biasing one or more lift pins during substrate processing, according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to methods and apparatus for equalizing plasma distribution above a substrate support in order to eliminate or minimize discontinuity marks formed during plasma enhanced chemical vapor deposition (PECVD) of a material layer onto a large area substrates. Discontinuity marks, corresponding to lift pin configurations in the substrate support, can be eliminated or minimized by biasing or by grounding desired lift pins. To prevent shorting between biased or grounded lift pins and the substrate support, the lift pins are electrically isolated from the substrate support. In one embodiment, one or more biased or grounded lift pins are electrically isolated from the substrate support by an electrically insulating material disposed on surfaces of the one or more lift pins. In another embodiment, one or more lift pins are electrically isolated from the substrate support by an electrically insulating material disposed on the walls of one or more respective openings formed through the substrate support.

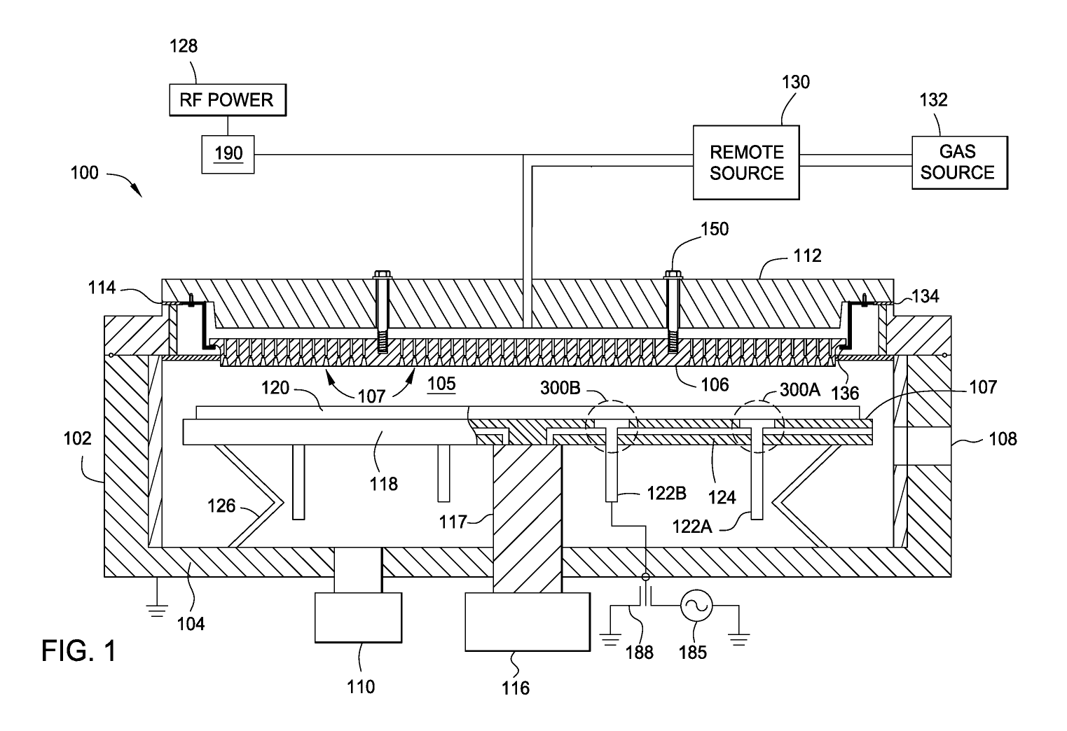

FIG. 1 is a schematic, cross sectional view of a PECVD processing chamber 100. The processing chamber 100 generally includes one or more chamber walls 102, a chamber base 104, and a gas distribution assembly 106, typically known as a showerhead, which define a processing volume 105. The gas distribution assembly 106 is coupled to a backing plate 112 by one or more fastening mechanisms 150 to help prevent sag and/or control the straightness/curvature of the gas distribution assembly 106. A gas source 132, fluidly coupled to the backing plate 112, provides processing gases to the processing volume 105 through a plurality of first openings 107 formed through the gas distribution assembly 106. The processing volume 105, having a substrate support disposed therein 118, is fluidly coupled to an exhaust 110, such as one or more dedicated vacuum pumps, which maintain the processing volume 105 at a sub-atmospheric conditions and evacuate processing gases and other gases therefrom. An RF source 128, is electrically coupled to the backing plate 112 and, or, to the gas distribution assembly through a match network 190. During substrate processing, RF power provided by the RF source 128 is used to ignite and maintain a processing plasma from the processing gases through capacitive energy coupling therewith. In some embodiments, a remote plasma source 130, such as an inductively coupled remote plasma source 130, is coupled between the gas source 132 and the backing plate 112. Between processing substrates, a cleaning gas may be provided to the remote plasma source 130 and a remote plasma generated therein. The radicals from the remote plasma are then flow into the processing volume 105 to clean surfaces therein.

The gas distribution assembly 106 herein is further coupled to the backing plate 112 by a showerhead suspension 134, such as a flexible metal skirt. Typically, the showerhead suspension 134 includes a lip 136 upon which at least a portion of the gas distribution assembly 106 rests. In some embodiments, the backing plate 112 rests on an upper surface of a ledge 114 of the chamber walls 102 which seals the processing volume 105 from atmospheric conditions.

The substrate support 118 is disposed on a shaft 117 sealingly extending through the chamber base 104. The shaft 117 is coupled to an actuator 116 which is used to raise and lower the shaft 117, and the thus substrate support 118 disposed thereon, to facilitate processing of a substrate 120 and transfer thereof to and from the processing volume 105. The substrate 120 is loaded into the processing volume 105 through a second opening 108 in one of the one or more chamber walls 102, which is conventionally sealed with a door or a valve (not shown) during substrate processing. A plurality of lift pins, such as lift pins 122A, 122B, disposed above, but engageable with, the chamber base 104 are moveably disposed through the substrate support 118 to facilitate transferring of the substrate 120 to and from a substrate receiving surface thereof. When the substrate support 118 is in a lowered position the plurality of lift pins 122A, 122B contact the chamber base 104 and are moved to extend above the substrate support 118 lifting the substrate 120 from the substrate receiving surface and enabling access to the substrate 120 by a robot handler (not shown). When the substrate support 118 is in a raised and, or, processing position, the tops of the plurality of lift pins 122A, 122B are flush with or below the substrate receiving surface of the substrate support 118 and the substrate 120 rests thereon. In some embodiments, the substrate support 118 further includes heating and/or cooling elements 124 to maintain the substrate support 118, and thus the substrate 120 disposed thereon at a desired temperature. Typically, the substrate support 118 is electrically coupled to one or more RF return straps 126 to provide an RF return path at the periphery thereof.

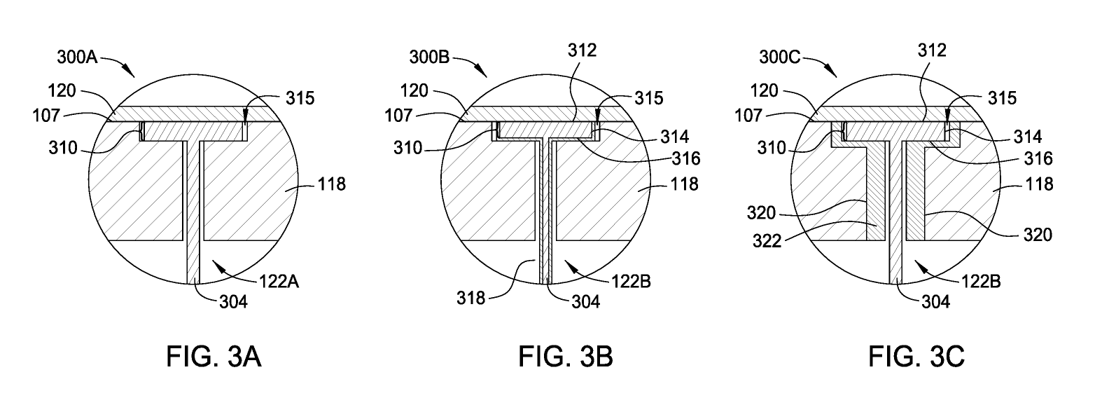

Herein, the plurality of lift pins 122A, 122B include one or more edge lift pins 122A for edge and corner support of the substrate 120 during substrate transfer and one or more inner lift pins 122B for center support of the substrate 120, where center support includes locations radially inward from the locations of the edge lift pins 122A in a direction towards the center of the substrate support 118. Typically, each of the plurality of lift pins 122A,122B include an elongated shaft 304 (See FIGS. 3A-3C) and a head 310 (See FIGS. 3A-3C) with a top surface 312 (See FIGS. 3A-3C) for contacting the substrate 120, sides 314 (See FIGS. 3A-3C), and a bottom surface 316 (See FIGS. 3A-3C).

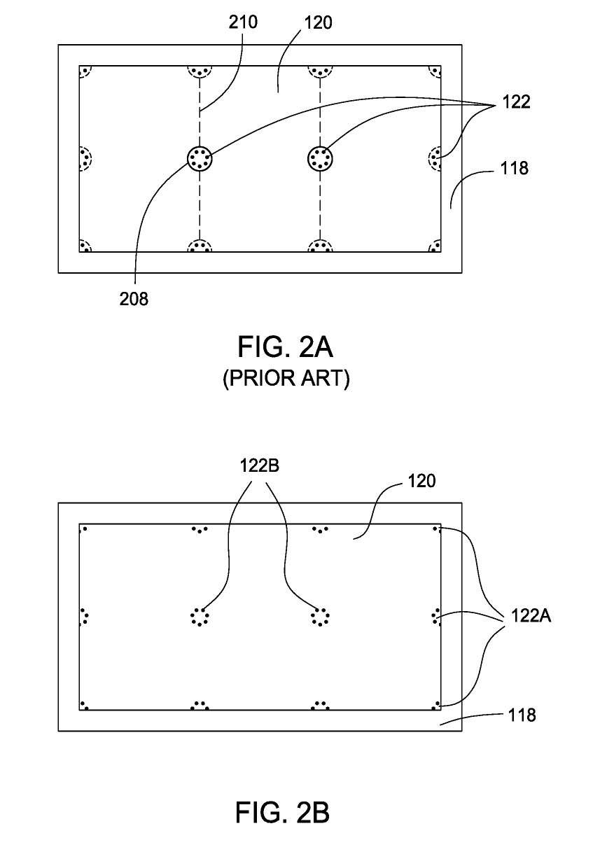

In one embodiment, the one or more inner lift pins 122B are electrically coupled to a bias potential source 185, such as an RF source. A bias voltage provided to the one or more inner lift pins 122B provides for equalized capacitive energy coupling with the plasma, formed thereabove, across the surfaces of the substrate support 118 and the one or more inner lift pins 122B disposed therethrough. The equalized plasma energy coupling provides a uniform plasma distribution that substantially eliminates or minimizes film deposition discontinuities on the substrate in regions above the one or more inner lift pins 122B, compared to the substrate surfaces proximate thereto, which eliminates and, or, minimizes discontinuity marks in the deposited film, such as the discontinuity marks 208 described in FIG. 2A.

In another embodiment, the one or more inner lift pins 122B are coupled to an earthen ground 188 and the grounded one or more inner lift pins 122B are each electrically isolated from the substrate support 118.

FIG. 2A illustrates a substrate 120 disposed on a substrate support 118 with a lift pin 122 configuration in accordance with the prior art. As shown, a plurality of undesirable discontinuity marks 208, also known as golf tee mura, form in and, or on the film deposited on the substrate 120 in a respective plurality of regions proximate to and, or, above each of the plurality of lift pins 122. The discontinuity marks 208 that appear in the regions where one or more lift pins 122 are disposed inward of the perimeter of the substrate 120 are often visible to the naked eye as discolored spots. It is believed that these defects are caused by film heterogeneity due to discontinuous plasma coupling over these supporting areas. As shown in FIG. 2A, discontinuity marks 208 in and, or, on the surface of the substrate 120 above lift pins 122 are visible after the PECVD process. To avoid discontinuity marks 208 in final products, final product dimensions are undesirably limited by the cut lines 210 necessary to avoid discontinuity marks 108, caused by the lift pins 122 in the inner of the substrate support 118.

FIG. 2B illustrates a substrate 120 on a substrate support 118 with a lift pin 122 configuration in accordance with embodiments disclosed herein. In one embodiment the substrate 120 is disposed on the substrate support 118 and one or more inner lift pins 122B are located inward from the edges of the substrate 120. The one or more inner lift pins 122B are coupled to a bias potential source 185 in one embodiment or to an earthen ground 188 in another embodiment. The one or more inner lift pins 122B are electrically isolated from the substrate support 118. In one embodiment, a bias voltage is applied to the one or more inner lift pins 122B to equalize capacitive energy coupling with the plasma formed thereabove across the substrate support 118 and the one or more inner lift pins 122B, and provide uniform plasma distribution across the surface of the substrate 120.

FIG. 3A is an enlarged view of a portion of the edge lift pin 122A, the substrate support 118, and the substrate 120. The edge lift pin 122A is movably disposed within the substrate support 118. In one embodiment, the edge lift pin 122A comprises a metal or metal alloy, a ceramic material, or any material that is able to withstand high temperatures and is not reactive to process chemistry. In some embodiments, a recessed gap 315 is provided in the substrate support 118 to facilitate any thermal expansion of the head 310 when the head 310 is exposed to elevated processing temperatures.

FIG. 3B is an enlarged view of one embodiment of a portion of an inner lift pin 122B, the substrate support 118, and the substrate 120. In this embodiment, one or more inner lift pins 122B has an elongated shaft 304 and a head 310, the head 310 having a top surface 312, sides 314, and a bottom surface 316. The elongated shaft 304 and the head 310 of one or more inner lift pins 122B are made of an electrically conductive metal, such as aluminum or anodized aluminum. The elongated shaft 304 and the sides 314 and the bottom surface 316 of the head 310 have an electrically insulating material, such as an insulative coating 318, disposed thereon so that the one or more inner lift pins 122B are electrically isolated from the substrate support 118 when the substrate support 118 is in a raised, i.e., processing, position as shown in FIG. 1. The insulative coating 318 can be made from any material that is electrically non-conductive, is able to withstand high temperatures, and is not reactive to process chemistry, such as a ceramic material, for example Al₂O₃, AlN, Y₂O₃, or combinations thereof, some polymers, and the like. In some embodiments, a recessed gap 315 may be provided in the substrate support 118 to facilitate any thermal expansion of the head 310 and/or insulative material when the lift pin 122B is exposed to elevated processing temperatures.

FIG. 3C is an enlarged view of another embodiment of a portion of an inner lift pin 122B, the substrate support 118, and the substrate 120. In this embodiment, one or more inner lift pins 122B each have an elongated shaft 304 and a head 310. The elongated shaft 304 and the head 310 of the one or more inner lift pins 1226 are made of an electrically conductive metal, such as aluminum or anodized aluminum.

An opening in the substrate support 118 is bounded by opening walls 320 defining the opening. The opening walls 320 have a liner 322 so that the one or more inner lift pins 122B are electrically isolated from the substrate support 118 when the substrate support is in a raised position, as shown in FIG. 1. The liner 322 herein is formed of any material that is electrically non-conductive, is able to withstand high temperatures, and is not reactive to process chemistry, such as a ceramic material, for example Al₂O₃, AlN, Y₂O₃, or combinations thereof, some polymers, and the like. In one embodiment, a recessed gap 315 is provided in the substrate support 118 to facilitate any thermal expansion of the head 310 and/or the liner 322 when the lift pin 122B is exposed to elevated processing temperatures.

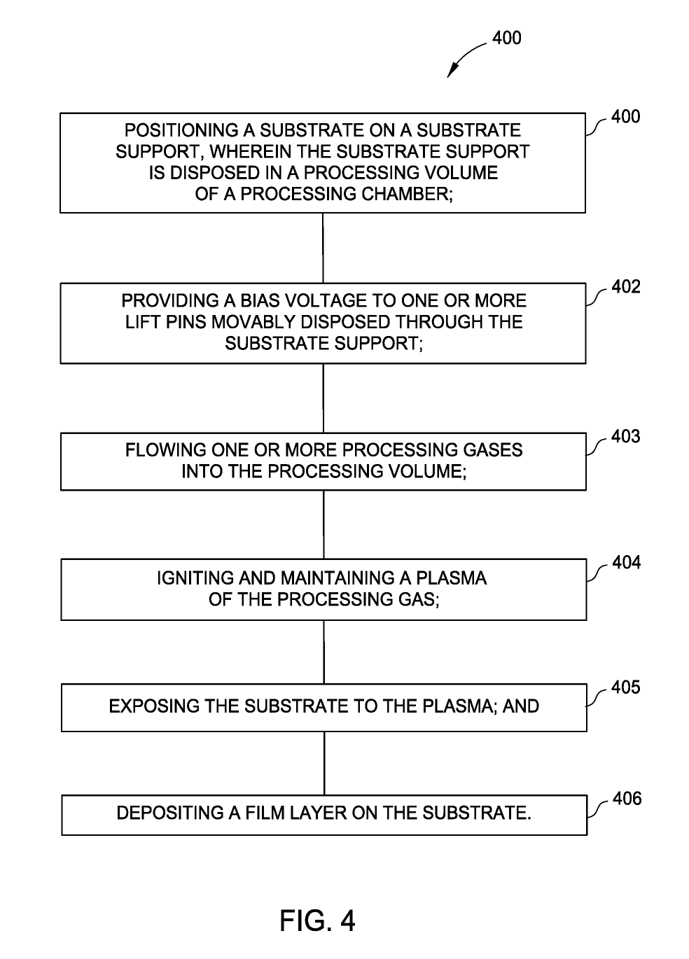

FIG. 4 is a flow diagram of a method of biasing one or more lift pins during substrate processing, according to one embodiment. At activity 401 the method 400 includes positioning a substrate on a substrate support, the substrate support disposed in a processing volume of a processing chamber, such as the processing chamber in FIG. 1. At activity 402 the method 400 includes applying a bias voltage to one or more lift pins movably disposed through the substrate support. In some embodiments, the one or more lift pins are disposed inward from the edges of the substrate support in a direction towards the inner thereof. At activity 403 the method 400 includes flowing one or more processing gases into the processing volume. At activity 404 the method 400 includes igniting and maintaining a plasma of the processing gases. At activities 405 and 406 the method 400 includes exposing the substrate to the plasma and depositing a material layer thereon.

The apparatus and methods described herein provide for the elimination and, or, minimization of discontinuity marks, also known as golf tee mura, on and, or, in a material layer deposited using a plasma enhanced CVD process by equalizing capacitive energy coupling with the plasma across the surface of a substrate support, including across the surfaces of lift pins disposed therethrough. To prevent shorting between biased or grounded lift pins and the substrate support, the biased or grounded lift pins described herein are electrically isolated from the substrate support. In some embodiments, the lift pins are electrically isolated from the substrate support by a coating of electrically insulating material disposed on the lift pins. In other embodiments, the lift pins are electrically isolated from the substrate support by lining the openings formed in the substrate support with an electrically insulating material.

While the foregoing is directed to embodiments of the present disclosure, other and further embodiments of the disclosure may be devised without departing from the basic scope thereof, and the scope thereof is determined by the claims that follow.

1. A processing chamber, comprising:
a chamber body defining a processing volume;
a substrate support disposed within the processing volume, wherein the substrate support has a plurality of openings formed therethrough;
one or more first lift pins respectively disposed through one or more first openings of the plurality of openings; and
one or more second lift pins respectively disposed through one or more second openings of the plurality of openings, wherein the one or more second lift pins are electrically isolated from the substrate support.

2. The processing chamber of claim 1, wherein the one or more second lift pins are electrically coupled to a bias potential source.

3. The processing chamber of claim 2, wherein the one or more second lift pins are formed of an electrically conductive metal.

4. The processing chamber of claim 3, wherein the electrically conductive metal is aluminum.

5. The processing chamber of claim 3, wherein the one or more second lift pins further comprise an electrically non-conductive material disposed on the electrically conductive metal.

6. The processing chamber of claim 5, wherein the electrically non-conductive material is ceramic.

7. The processing chamber of claim 3, wherein walls defining the one or more second openings are lined with a non-conductive material.

8. The processing chamber of claim 1, wherein the one or more second lift pin are disposed in an arrangement inward from one or more first lift pins in a direction towards the inner of the substrate support.

9. The processing chamber of claim 8, wherein the non-conductive material is ceramic.

10. The processing chamber of claim 1, wherein the one or more second lift pins are electrically coupled to ground.

11. The processing chamber of claim 1, further comprising a gas distribution assembly facing the substrate support.

12. The processing chamber of claim 11, wherein the gas distribution assembly is electrically coupled to an RF power supply.

13. A processing kit, comprising:
one or more lift pins, each comprising:
an elongated shaft coupled to a head, the head having a top surface, sides, and a bottom surface, wherein the elongated shaft and the head are formed of an electrically conductive metal; and
an electrically non-conductive material disposed on the elongated shaft, the sides of the head, and the bottom surface of the head.

14. The processing kit of claim 13, wherein the electrically conductive metal is aluminum.

15. The processing kit of claim 11, wherein the electrically non-conductive material is ceramic.

16. A method of processing a substrate, comprising:
positioning a substrate on a substrate support, wherein the substrate support disposed in a processing volume of a processing chamber;
applying a bias voltage to one or more lift pins movably disposed through the substrate support;
flowing a processing gas into the processing volume;
igniting and maintaining a plasma of the processing gas;
exposing the substrate to the plasma; and
depositing a material layer on the substrate.

17. The method of claim 16, wherein the one or more lift pins are disposed inward from the edges of the substrate support in a direction towards the center thereof.

18. The method of claim 17, wherein the one or more lift pins, each comprise:
an elongated shaft coupled to a head, the head having a top surface, sides, and a bottom surface, wherein the elongated shaft and the head are formed of an electrically conductive metal; and
an electrically non-conductive material disposed on the elongated shaft, the sides of the head, and the bottom surface of the head.

19. The method of claim 18, wherein the electrically conductive metal is aluminum.

20. The method of claim 18, wherein the electrically non-conductive material is ceramic.
